(19) United States
(12) Patent Application Publication
(10) Pub. No.: US 2012/0034749 A1
(43) Pub. Date: Feb. 9, 2012

(54) METHOD FOR MANUFACTURING A STRAINED SEMICONDUCTOR DEVICE

(75) Inventors: Kwan-Yong LIM, Seongnam-si (KR); Chung-Geun Koh, Seoul (KR); Hyun-Jung Lee, Suwon-si (KR); Tae-Ouk Kwon, Hwaseong-si (KR); Seok-Hoon Kim, Hwaseong-si (KR); Tae-Ho Cha, Yongin-si (KR)

(73) Assignee: Samsung Electronics Co., Ltd.

(21) Appl. No.: 13/197,658

(22) Filed: Aug. 3, 2011

(30) Foreign Application Priority Data
Aug. 6, 2010 (KR) 10-2010-0075943

(51) Int. Cl. H01L 21/336

(52) U.S. Cl. 438/303; 257/E21.409

(57) ABSTRACT

A method of manufacturing a semiconductor device can be provided by forming a gate structure on a substrate and forming a diffusion barrier layer on the gate structure and the substrate, A stress layer can be formed on the diffusion barrier layer comprising a metal nitride or a metal oxide having a concentration of nitrogen or oxygen associated therewith. The stress layer can be heated to transform the stress layer into a tensile stress layer to reduce the concentration of the nitrogen or the oxygen in the stress layer. The tensile stress layer and the diffusion barrier layer can be removed.

### CROSS-REFERENCE TO RELATED APPLICATIONS

This application claims priority under 35 USC § 119 to Korean Patent Application No. 10-2010-0075943, filed on Aug. 6, 2010 in the Korean Intellectual Property Office (KIPO), the entire content of which is incorporated herein by reference.

### BACKGROUND OF THE INVENTION

1. Field

Example embodiments relate to a method of manufacturing a semiconductor device. More particularly, example embodiments relate to a method of manufacturing a strained semiconductor device.

2. Description of the Related Art

By generating tensile stress (or strain) or compressive stress in a channel of a transistor, the mobility of carriers in the channel can be improved. For this purpose, stress memorization technique (SMT), which includes applying stress on a channel in a substrate by forming a stress layer having a tensile stress or a compressive stress on the substrate and by performing a heat treatment thereon, and removing the stress layer therefrom, has been developed.

In the SMT, for example, a silicon nitride layer serving as a tensile stress layer having a tensile stress may be formed on a substrate, and before forming the silicon nitride layer, a silicon oxide layer may be formed on the substrate so that the substrate may not be damaged when the silicon nitride layer is removed afterward. Accordingly, the stress of the silicon nitride layer may not be transferred to the substrate effectively due to the interposed silicon oxide layer, and an isolation layer on the substrate may be partially removed when the silicon oxide layer is removed.

### SUMMARY OF THE INVENTION

In some embodiments according to the inventive concept, methods of manufacturing strained semiconductor devices can be provided. Pursuant to these embodiments, a method of manufacturing a semiconductor device can be provided by forming a gate structure on a substrate and forming a diffusion barrier layer on the gate structure and the substrate. A stress layer can be formed on the diffusion barrier layer comprising a metal nitride or a metal oxide having a concentration of nitrogen or oxygen associated therewith. The stress layer can be heated to transform the stress layer into a tensile stress layer to reduce the concentration of the nitrogen or the oxygen in the stress layer. The tensile stress layer and the diffusion barrier layer can be removed.

In example embodiments, the stress layer may have a compressive stress prior to the heat treatment.

In example embodiments, the metal nitride may include tungsten nitride (WNx), ruthenium nitride (RuNx), cobalt nitride (CoNx) or nickel nitride (NiNx).

In example embodiments, the metal nitride may include tungsten nitride (WNx).

In example embodiments, x may be in a range of 0.05 to 0.4

In example embodiments, the metal oxide may include tungsten oxide (WO3) or ruthenium oxide (RuO2)

In example embodiments, the heat treatment may be performed at a temperature of about 500° C. to about 1250° C.

In example embodiments, a removing the tensile stress layer may be performed using a hydrogen peroxide solution, a sulfuric acid solution or a nitric acid solution.

In example embodiments, the diffusion barrier layer may be formed using silicon oxide (SiO2) or silicon nitride (SiN).

In example embodiments, the diffusion barrier layer may be formed to have a thickness of about 5 Å to about 20 Å

In example embodiments, prior to forming the diffusion barrier layer, an amorphous ion implantation region may be further formed at an upper portion of the substrate using the gate structure as an ion implantation mask.

In example embodiments, the amorphous ion implantation region may be transformed into a crystalline ion implantation region having a compressive stress by the heat treatment.

In example embodiments, forming the amorphous ion implantation region may include implanting silicon ions or germanium ions the substrate.

In example embodiments, after forming the amorphous ion implantation region, a spacer may be further formed on a sidewall of the gate structure.

In example embodiments, an impurity region may be further formed at an upper portion of the substrate adjacent to the gate structure

In example embodiments, forming the impurity region may be performed using an n-type impurities.

In some embodiments according to the inventive concept, a method of manufacturing a strained semiconductor device can be provided by forming a first gate structure and a second gate structure on a substrate. A diffusion barrier layer and a stress layer can be formed on the gate structures and the substrate, where the stress layer comprising a metal nitride or a metal oxide. A first heat treatment can be performed to transform the stress layer into a tensile stress layer to reduce the concentration of the nitrogen or the oxygen in the stress layer. The tensile stress layer and the diffusion barrier layer can be removed. An etch stop layer and a compressive stress layer can be formed on the gate structures and the substrate, where the compressive stress layer comprising silicon nitride. A second heat treatment can be performed on the substrate and the compressive stress layer and the etch stop layer can be removed.

In example embodiments, prior to forming the stress layer, a first amorphous ion implantation region may be formed by implanting ions into an upper portion of the substrate using the first gate structure as an ion implantation mask. Prior to forming the compressive stress layer, a second amorphous ion implantation region may be formed by implanting ions into an upper portion of the substrate using the second gate structure as an ion implantation mask. The first amorphous ion implantation region may be transformed into a first crystalline ion implantation region having a compressive stress by the first heat treatment and the second amorphous ion implantation region may be transformed into a second crystalline ion implantation region having a tensile stress by the second heat treatment.

In example embodiments, the diffusion barrier layer may be formed using silicon oxide or silicon nitride and the etch stop layer may be formed using silicon oxide.

In example embodiments, a first impurity region may be formed by doping n-type impurities at an upper portion of the substrate adjacent to the first gate structure. A second impurity region may be formed by doping p-type impurities at an upper portion of the substrate adjacent to the second gate structure.

In some embodiments according to the inventive concept, a method of forming a semiconductor device can be provided by forming a stress layer and a diffusion barrier layer on a gate structure, where the stress layer comprising a metal nitride or a metal oxide having an initial concentration of nitrogen associated therewith. The stress layer can be heated to transform the stress layer into a tensile stress layer to reduce the initial concentration of the nitrogen to less than about 0.06 Cn in the stress layer. The tensile stress layer and the diffusion barrier layer can be removed.

In some embodiments according to the inventive concept, the initial concentration of nitrogen can be less than about 0.5 Cn. In some embodiments according to the inventive concept, heating the stress layer to transform the stress layer into a tensile stress layer changes a stress associated with the stress layer by more than about 2 Gpa.

According to some example embodiments, by using a stress layer including a metal nitride or a metal oxide, the stress layer may be removed using a hydrogen peroxide solution which may not react with silicon or silicon oxide afterward. As a thick etch stop layer may not need to be formed on a substrate, the stress may be transferred from the stress layer into the substrate efficiently. Additionally, an etch stop layer including silicon oxide may not need to be removed so that the damage of an isolation layer may be prevented. Moreover, as the stress layer may have a high tensile stress, a high stress may be introduced into a channel of a transistor to improve a mobility of a carrier. Meanwhile, the stress layer may not include hydrogen so that the negative bias temperature instability (NBTI) by the escape of hydrogen the may not be occurred.

### BRIEF DESCRIPTION OF THE DRAWINGS

FIGS. 1 to 7 are cross-sectional views illustrating methods of manufacturing strained semiconductor devices in some embodiments according to the inventive concept.

FIG. 8 is a graph illustrating stress versus nitrogen concentration contained in a tungsten nitride layer.

FIGS. 9 to 21 are cross-sectional views illustrating methods of manufacturing strained semiconductor devices in some embodiments according to the inventive concept.

### DETAILED DESCRIPTION

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc, may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

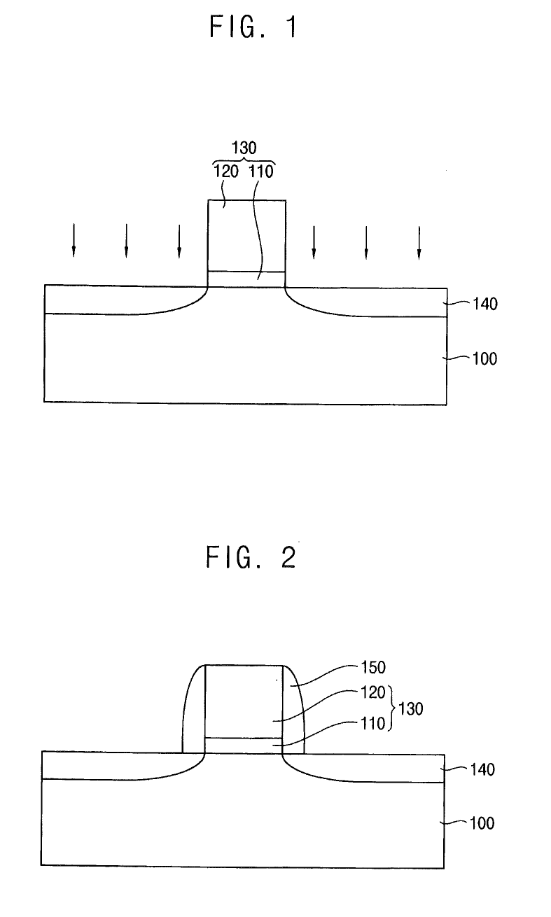

FIGS. 1 to 7 are cross-sectional views illustrating methods of manufacturing strained semiconductor devices in some embodiments according to the inventive concept.

FIG. 8 is a graph illustrating stress versus nitrogen concentration contained in a tungsten nitride layer.

Referring to FIG. 1, a gate structure 130 may be formed on a substrate 100.

The substrate 100 may include a semiconductor substrate such as a silicon substrate, germanium substrate or a silicon-germanium substrate, a silicon-on-insulator (SOI) substrate or a germanium-on-insulator (GOI) substrate.

The gate structure 130 may be formed to include a gate insulation layer pattern 110 and gate electrode 120 sequentially stacked on the substrate 100.

The gate insulation layer pattern 110 may be formed using silicon oxide or silicon oxynitride, and the gate electrode 120 may be formed using doped polysilicon, a metal, a metal nitride and/or a metal silicide.

By implanting ions into the substrate 100 using the gate structure 130 as an ion implantation mask, an amorphous ion implantation region 140 may be formed at an upper portion of the substrate 100 adjacent to the gate structure 130. In example embodiments, silicon ions or germanium ions may be implanted into the substrate 100. As the ions are implanted into the substrate 100, the upper portion of the substrate 100 may become amorphous, thereby to form the amorphous ion implantation region 140.

In example embodiments, a second impurity region(not shown) may be further formed at an upper portion of the substrate 100 adjacent to the gate structure 130, by implanting second impurities into the substrate 100 using the gate structure 130 as an ion implantation mask. The second impurities may be n-type impurities such as phosphorus or arsenic. In an example embodiment, the second impurity region may be formed in the amorphous ion implantation region 140. Alternatively, the second impurity region may be formed in the substrate 100 to have a volume larger than the amorphous ion implantation region 140.

The formation of the second impurity region may be performed prior to or simultaneously with the formation of the amorphous ion implantation region 140.

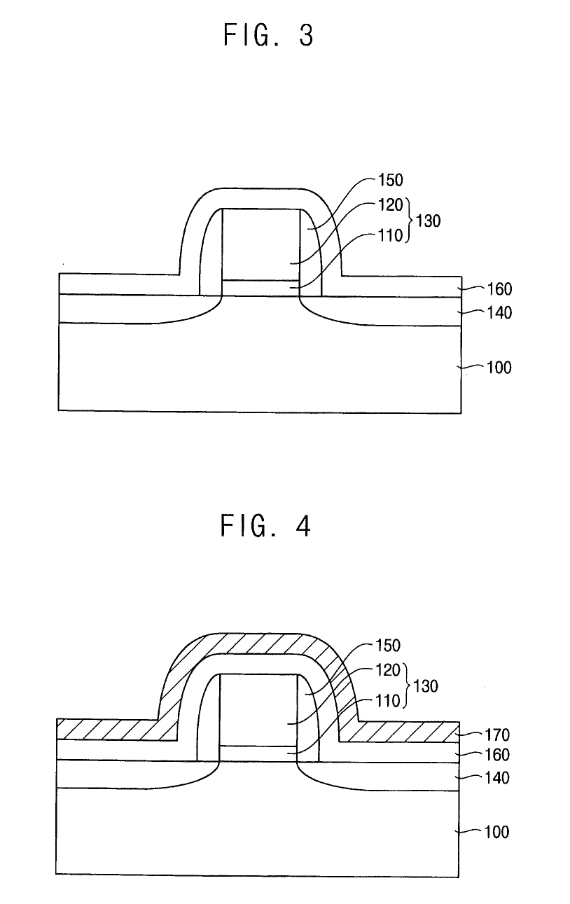

Referring to FIG. 2, a spacer 150 may be formed on a sidewall of the gate structure 130. The spacer 150 may be formed using silicon oxide or silicon nitride. Alternatively, the spacer 150 may be formed after removing a stress layer 170 and a diffusion barrier layer 160 (see FIGS. 3 and 4).

Referring to FIG. 3, the diffusion barrier layer 160 may be formed on the substrate 100 having the gate structure 130 and the spacer 150 thereon. The diffusion barrier layer 160 may be formed using silicon oxide (SiO2) or silicon nitride (SiN). In example embodiments, the diffusion barrier layer 160 may be formed on the gate structure 130, the spacer 150 and the substrate 100 by a chemical vapor deposition (CVD) process. Alternatively, the diffusion barrier layer 160 may be formed by oxidizing or nitriding upper surfaces of the gate structure 130 and the substrate 100. In an example embodiment, the diffusion barrier layer 160 may be formed to a thickness of about 5 Å to about 20 Å.

Referring to FIG. 4, the stress layer 170 may be formed on the diffusion barrier layer 160. The stress layer 170 may be formed using a metal nitride or a metal oxide. For example, the metal nitride may include tungsten nitride (WNx), ruthenium nitride (RuNx), cobalt nitride (CoNx), nickel nitride (NiNx), etc. When the stress layer 170 includes tungsten nitride (WNx), x may be in a range of 0.05 to 0.4. The metal oxide may include tungsten oxide (WO3), ruthenium oxide (RuO2), etc.

In example embodiments, the stress layer 170 may be a compressive stress layer having a compressive stress when the stress layer 170 is formed. Alternatively, the stress layer 170 may be also a tensile stress layer having a tensile stress according to a nitrogen concentration or an oxygen concentration thereof when the stress layer 170 is formed.

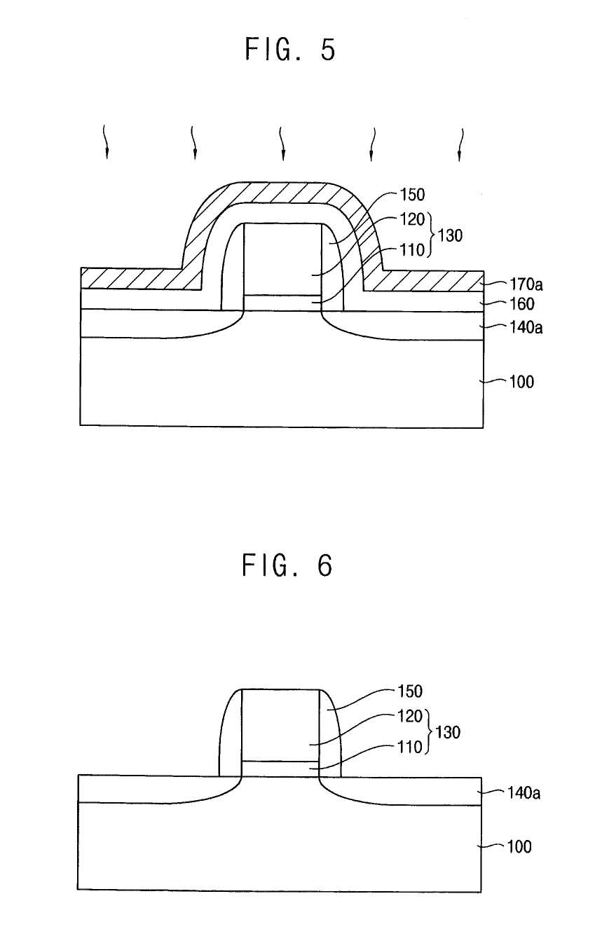

Referring to FIG. 5, a heat treatment may be performed on the substrate 100 on which the stress layer 170, the diffusion barrier layer 160, and the gate structure 130 may be formed. Accordingly, the amorphous ion implantation region 140 may be re-crystallized to form a crystalline ion implantation region 140a.

During the heat treatment, nitrogen or oxygen may be outgassed from the stress layer 170 so that a tensile stress layer 170a having a tensile stress may be formed. According to the heat treatment, the tensile stress layer 170a may include no nitrogen or no oxygen therein or include very little nitrogen or oxygen.

Referring to FIG. 8, when the stress layer 170 includes tungsten nitride, the stress layer 170 has a compressive stress at a high nitrogen concentration, while the stress layer 170 has a tensile stress at a nitrogen concentration below about 0.06, and further has a high tensile stress of about 1.6 GPa at a nitrogen concentration of about zero. Thus, the stress layer 170 including tungsten nitride may have a stress variation above about 2 GPa according to the reduction of the nitrogen concentration by the heat treatment, which is larger than a stress variation of the stress layer 170 including silicon nitride.

As described above, the stress layer 170 including a metal nitride or a metal oxide may be transformed into the tensile stress layer 170a having a high tensile stress by the heat treatment, so that the crystalline ion implantation region 140a under the tensile stress layer 170a may have a compressive stress in the heat treatment. As a result, an upper portion of the substrate 100 between the crystalline ion implantation regions 140a may have a tensile stress.

The heat treatment may be performed at a temperature of about 500° C. to about 1250° C., preferably at a temperature of about 850° C. to about 1000° C. When the temperature is lower than about 850° C., the crystallization efficiency may be poor, and when the temperature is higher than about 1000° C., underlying layers and the substrate 100 may be deteriorated.

Referring to FIG. 6, the tensile stress layer 170a may be removed from the substrate 100.

In example embodiments, the tensile stress layer 170a may be removed by a wet etching process using an etching solution having an etching selectivity between silicon (Si) or silicon oxide (SiO2) and a metal nitride layer or a metal oxide layer. For example, the wet etching process may be performed using hydrogen peroxide solution, sulfuric acid solution or nitric acid solution. Preferably, the wet etching process may be performed using the hydrogen peroxide solution. Alternatively, the tensile stress layer 170a may be removed by a dry etching process.

Thereafter, the diffusion barrier layer 160 may be also removed. The diffusion barrier layer 160 may be removed by a wet etching process or a dry etching process. As described above, the diffusion barrier layer 160 may be formed to have a thin thickness, and thus, for example, an isolation layer may not be damaged during the etching process.

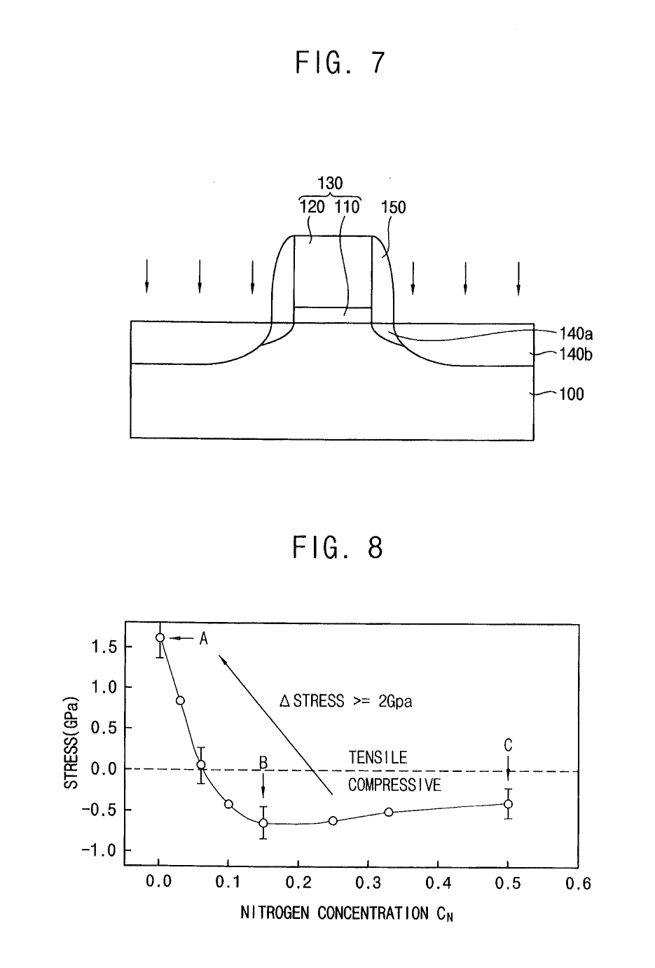

Referring to FIG. 7, a first impurity region 140b may be formed at an upper portion of the substrate 100 adjacent to the gate structure 130 by implanting first impurities into the substrate 100 using the gate structure 130 and the spacer 150 as an ion implantation mask. The first impurities may include n-type impurities such as phosphorus or arsenic. In example embodiments, a first impurity region 140b may be formed to have a deeper depth than that of the crystalline ion implantation region 140a. A heat treatment may be further performed on the substrate 100, after implanting the first impurities thereinto. The first impurity region 140b may serve as source/drain regions of a transistor.

As described above, a channel region of the transistor may have a high tensile stress due to the tensile stress layer 170a having a high tensile stress. Additionally, instead of a relatively thick etch stop layer, a relatively thin diffusion barrier layer 160 may be formed on the substrate 100 so that the stress of the tensile stress layer 170a may be transferred into the substrate 100 efficiently, and the damage of underlying layers may be reduced during the removing process of the diffusion barrier layer 160. Furthermore the stress layer 170 including a metal nitride or a metal oxide may not include hydrogen, and thus the deterioration of the underlying layers by the diffusion of hydrogen thereinto may be prevented.

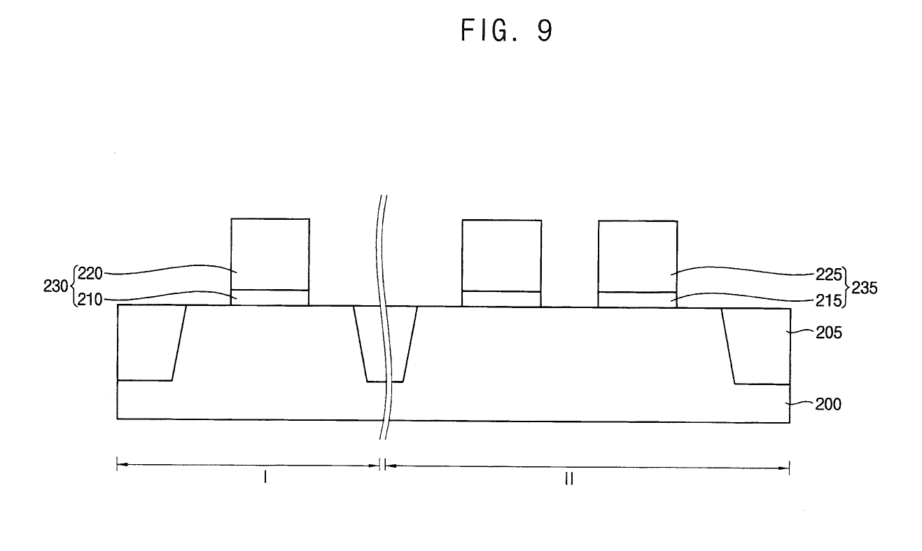

FIGS. 9 to 21 are cross-sectional views illustrating methods of manufacturing strained semiconductor devices in some embodiments according to the inventive concept. Processes substantially the same as or similar to those illustrated with reference to FIGS. 1 to 7 may be performed to form an NMOS transistor.

Referring to FIG. 9, first and second gate structures 230 and 235 may be formed on a substrate 200 on which an isolation layer 205 may be formed.

The isolation layer 205 may be formed on the substrate 200 by a shallow trench isolation (STI) process. The isolation layer 205 may define an active region and a field region in the substrate 200. Additionally, the substrate 200 may be divided into a first region I and a second region II. In example embodiments, the first region I may be a negative-channel metal oxide semiconductor (NMOS) region in which an NMOS transistor may be formed, and the second region II may be a positive-channel metal oxide semiconductor (PMOS) region in which a PMOS transistor may be formed.

The first gate structure 230 may be formed to include a first gate insulation layer pattern 210 and a first gate electrode 220 sequentially stacked on the substrate 200 in the first region I. The second gate structure 235 may be formed to include a second gate insulation layer pattern 215 and a second gate electrode 225 sequentially stacked on the substrate 200 in the second region II.

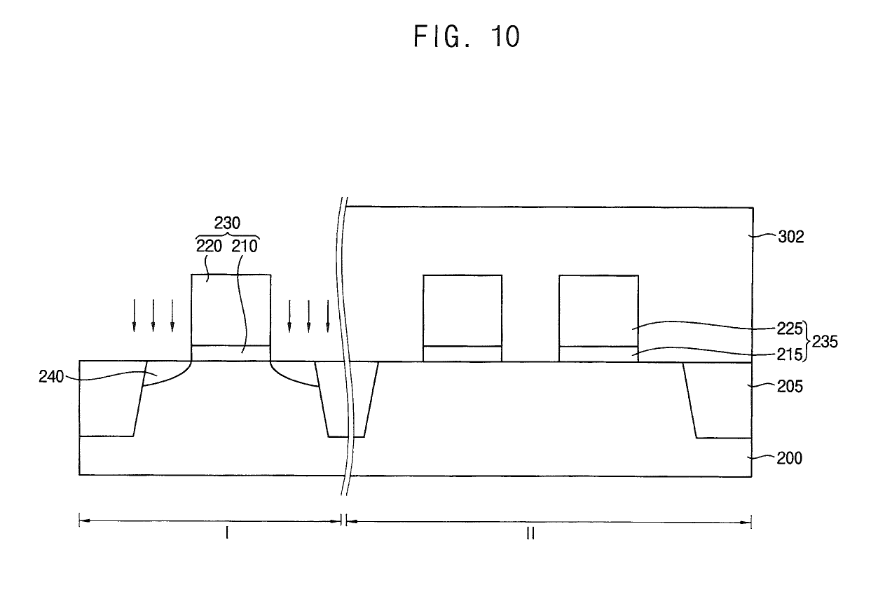

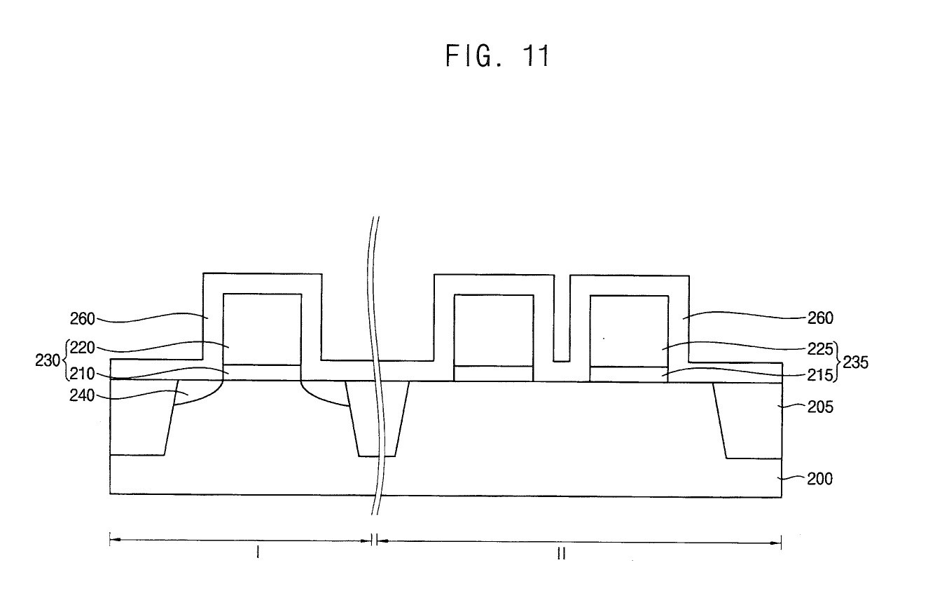

Referring to FIG. 10, a first mask 302 covering the second gate structure 235 may be formed on the substrate 200 in the second region II, and a first amorphous ion implantation region 240 may be formed at an upper portion of the substrate 200 adjacent to the first gate structure 230 by implanting silicon ions or germanium ions into the substrate 200 in the region I using the first gate structures 230 and the first mask 302 as an ion implantation mask.

A second impurity region (not shown) may be further formed at an upper portion of the substrate 200 adjacent to the first gate structure 230 by implanting second impurities into the substrate 200 in the first region I using the first gate structures 230 and the first mask 302 as an ion implantation mask. The second impurities may be n-type impurities such as phosphorus, arsenic, antimony, etc.

Thereafter, the first mask 302 may be removed.

Referring to FIG. 11, a diffusion barrier layer 260 may be formed on the substrate 200 having the gate structures 230 and 235 thereon. In example embodiments, the diffusion barrier layer 260 may be formed on the substrate 200, the gate structures 230 and 235, and the isolation layer 205. The diffusion barrier layer 260 may be formed using silicon oxide (SiO2) or silicon nitride (SiN). In an example embodiment, the diffusion barrier layer 260 may be formed to have a thin thickness of about 5 Å to about 20 Å.

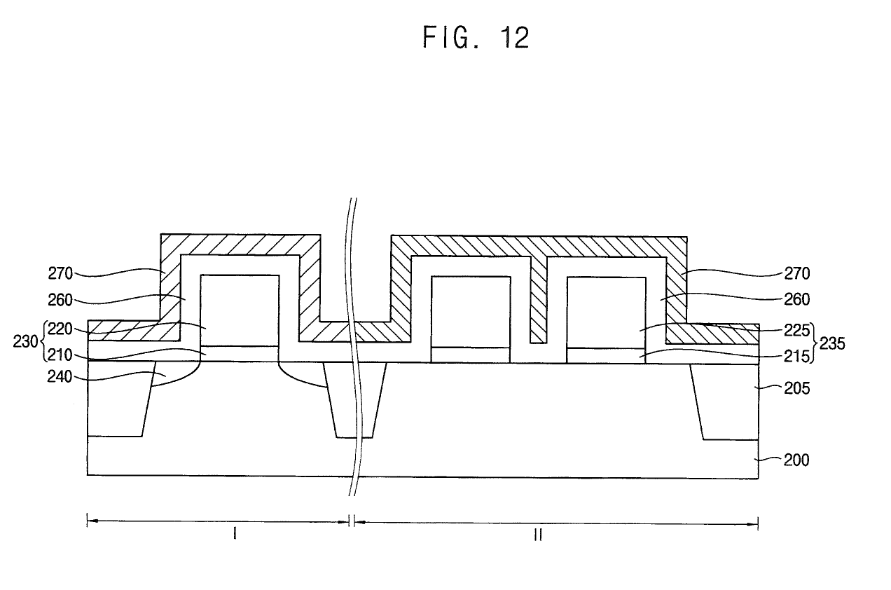

Referring to FIG. 12, a stress layer 270 may be formed on the diffusion barrier layer 260. The stress layer 270 may be formed using a metal nitride or a metal oxide. In example embodiments, the stress layer 270 may have a compressive stress when the stress layer 270 is formed.

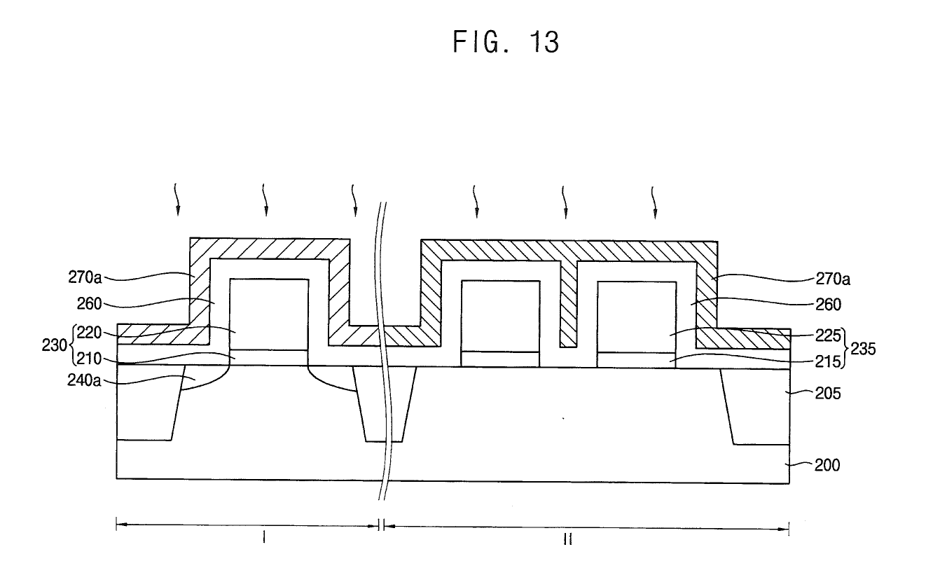

Referring to FIG. 13, a first heat treatment may be performed on the substrate 200 having the stress layer 270, the diffusion barrier layer 260, and the gate structures 230 and 235 thereon. Accordingly, the first amorphous ion implantation region 240 may be re-crystallized to form a first crystalline ion implantation region 240a.

During the first heat treatment, nitrogen or oxygen may be outgassed from the stress layer 270 so that a tensile stress layer 270a having a tensile stress may be formed. The first crystalline ion implantation region 240a formed under the tensile stress layer 270a may have a compressive stress in the heat treatment. As a result, an upper portion of the substrate 200 between the first crystalline ion implantation regions 240a may have a tensile stress.

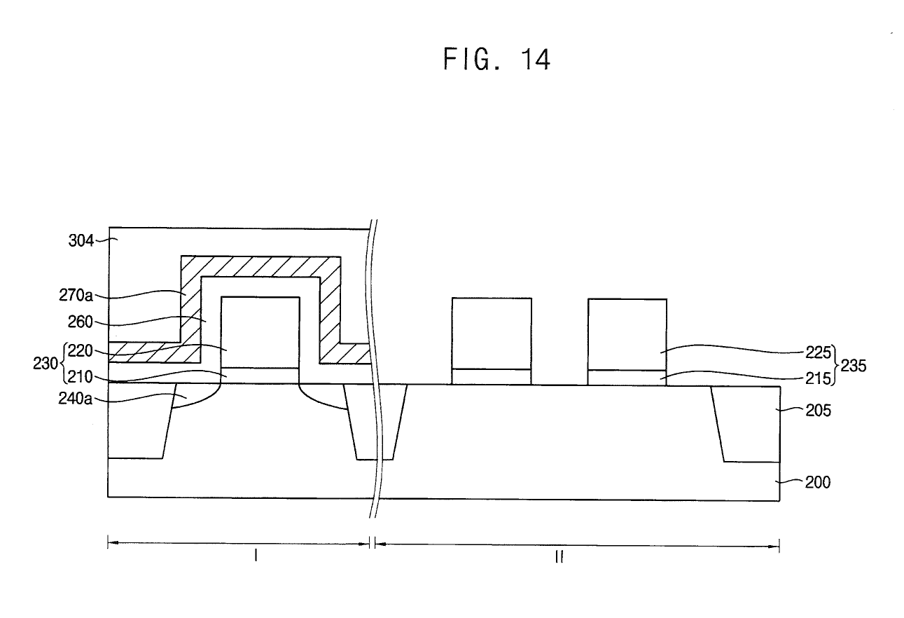

Referring to FIG. 14, after forming a second mask 304 covering the first gate structure 230 on the substrate 200 in the first region I, the tensile stress layer 270a and the diffusion barrier layer 260 on the substrate 200 in the second region II may be removed sequentially by using the second mask 304 as an etching mask. In example embodiments, the tensile stress layer 270a may be removed by a wet etching process using hydrogen peroxide solution, sulfuric acid solution or nitric acid solution.

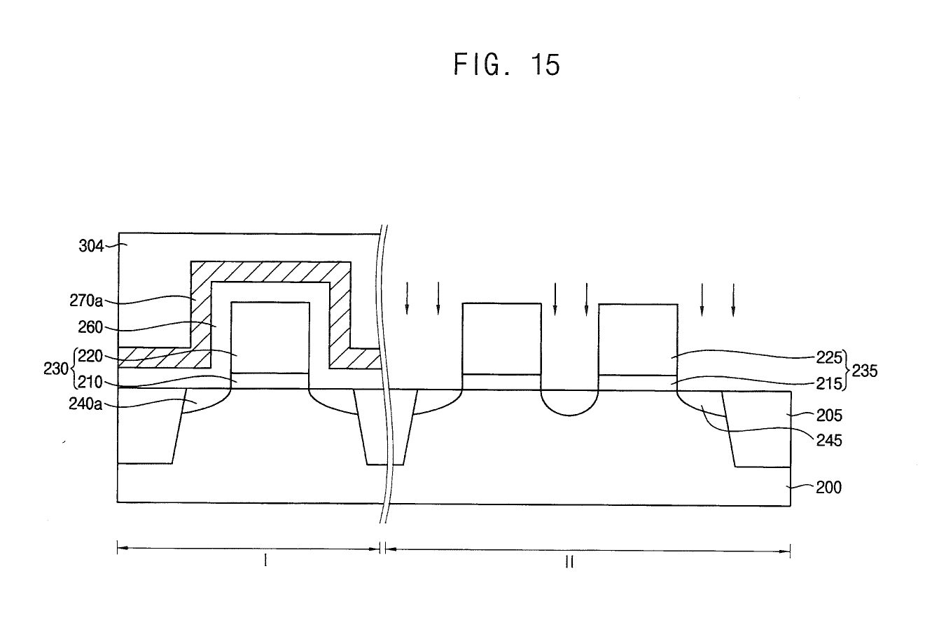

Referring to FIG. 15, a second amorphous ion implantation region 245 may be formed at an upper portion of the substrate 200 adjacent to the second gate structure 235 by implanting silicon ions or germanium ions into the substrate 200 in the second region II using the second mask 304 and the second gate structure 235 as an ion implantation mask.

A forth impurity region (not shown) may be further formed at an upper portion of the substrate 200 adjacent to the second gate structure 235, by implanting forth impurities into the substrate 200 in the second region II using the second gate structure 235 and the second mask 304 as an ion implantation mask. The forth impurities may be p-type impurities such as boron.

Thereafter, the second mask 304 may be removed from the substrate.

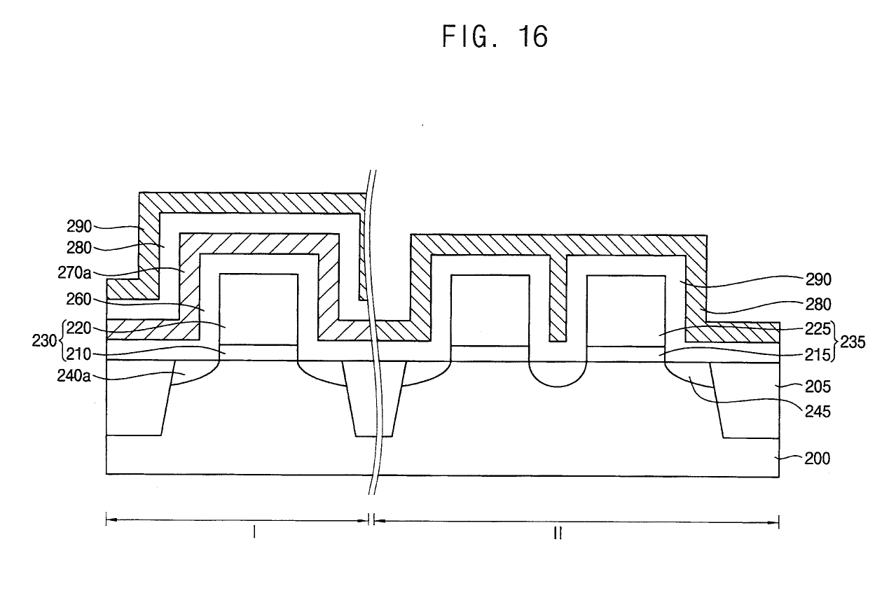

Referring to FIG. 16, a etch stop layer 280 and a compressive stress layer 290 may be formed sequentially on the substrate 200 in the second region II having the second gate structure 235 thereon. The etch stop layer 280 and the compressive stress layer 290 may be also formed on the remaining tensile stress layer 270a on the substrate 200 in the first region I.

In example embodiments, the etch stop layer 280 may be formed using silicon oxide (SiO2) or a metal. In an example embodiment, the etch stop layer 280 may be formed to have a thickness above about 30 Angstroms.

In example embodiments, the compressive stress layer 290 may be formed using silicon nitride by a plasma enhanced chemical vapor deposition (PECVD) process. During the PECVD process, the stress of the compressive stress layer 290 may be controlled by adjusting a pressure, a gas supplying rate, a substrate temperature, an ion dose, etc. In an example embodiment, the compressive stress layer 290 may be formed to have a compressive stress above about 2.5 GPa. In an example embodiment, the compressive stress layer 290 may be formed to have a thickness of about 100 Angstroms to about 500 Angstroms.

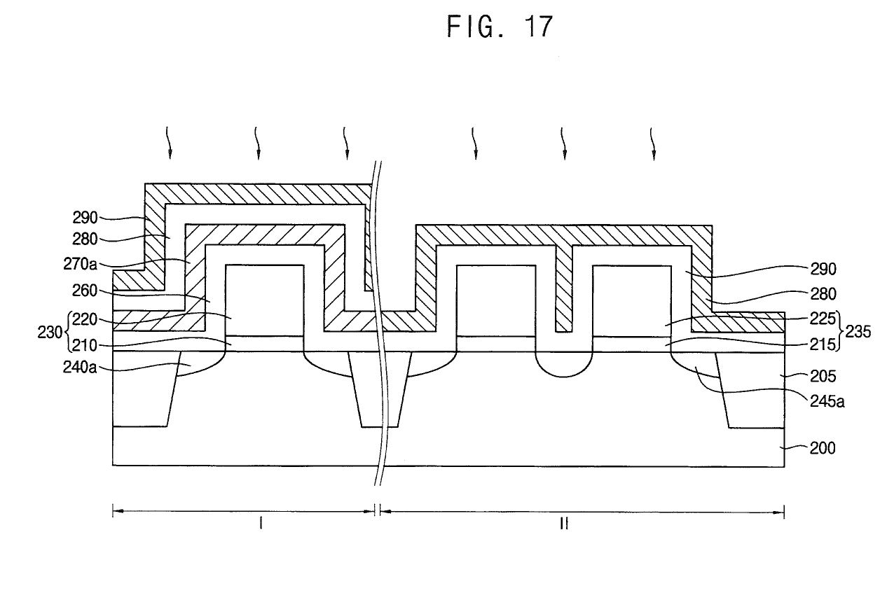

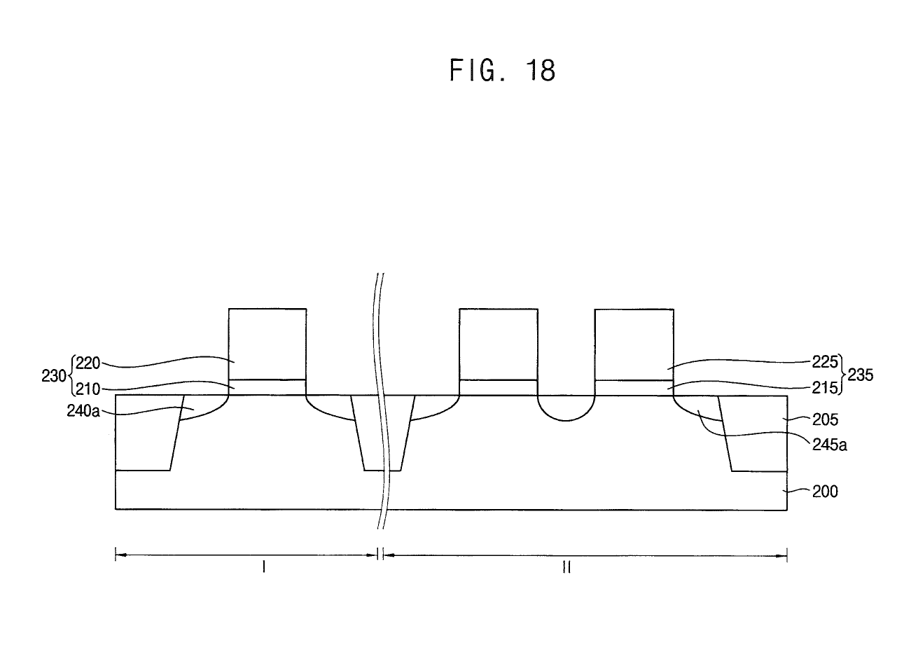

Referring to FIG. 17, a second heat treatment may be performed on the substrate 200 in the second region II having the compressive stress layer 290, the etch stop layer 280, and the second gate structure 235 thereon. Thus, the second amorphous ion implantation region 245 may be re-crystallization to form a second crystalline ion implantation region 245a and the second crystalline ion implantation region 245a may have a tensile stress. As a result, an upper portion of the substrate 200 between the second amorphous ion implantation regions 245 may have a compressive stress. Meanwhile, the first region I of the substrate 200 also may be heated together. However, the tensile stress layer 270a and the diffusion barrier layer 260 may be formed under the compressive stress layer 290 and the etch stop layer 280 and the ion implantation region 240a may be crystalline, so that the variation of the stress in the crystalline ion implantation region 240a may not be large.

Referring to FIG. 18, the compressive stress layer 290 and the etch stop layer 280 may be removed from the substrate 200.

In example embodiments, the compressive stress layer 290 may be removed by a wet etching process using an etching solution including phosphoric acid. Additionally, the etch stop layer 280 may be removed by a wet etching process using an etching solution including hydrogen fluoride.

Meanwhile, the remaining tensile stress layer 270a and the diffusion barrier layer 260 in the first region I may be removed. In example embodiments, the tensile stress layer 270a may be removed by a wet etching process using hydrogen peroxide solution, sulfuric acid solution or nitric acid solution.

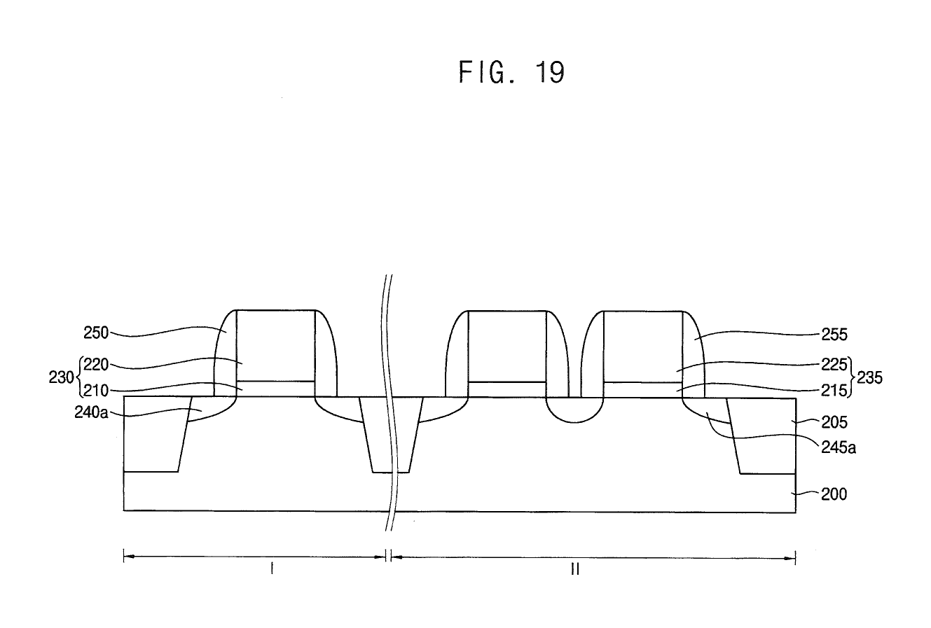

Referring to FIG. 19, a first spacer and a second spacer 250 and 255 may be formed on sidewalls of the first and the second gate structures 230 and 235 respectively. A spacer layer covering the first and the second gate structures 230 and 235 may be formed on the substrate 200 and may be etched anisotropically to form the spacers 250 and 255. The spacer layer may be formed using silicon oxide or silicon nitride.

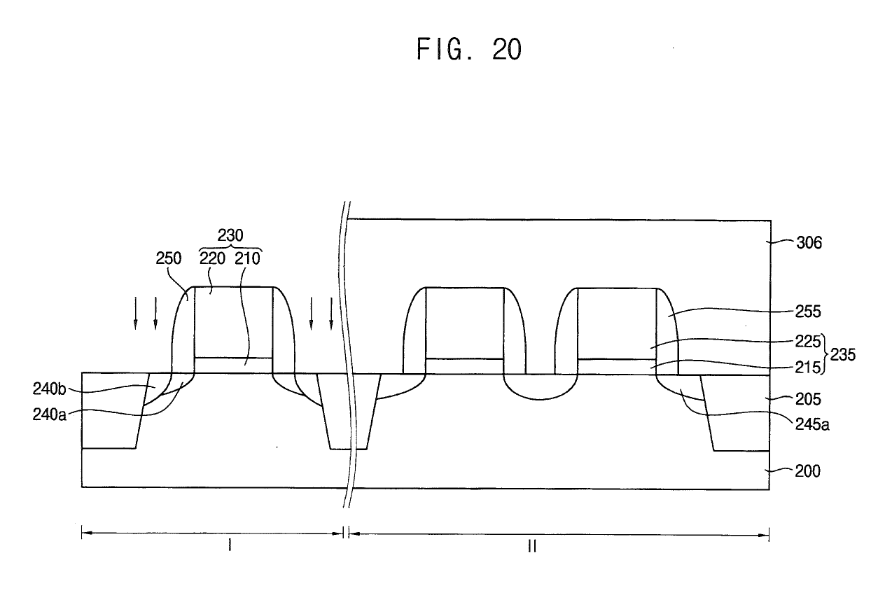

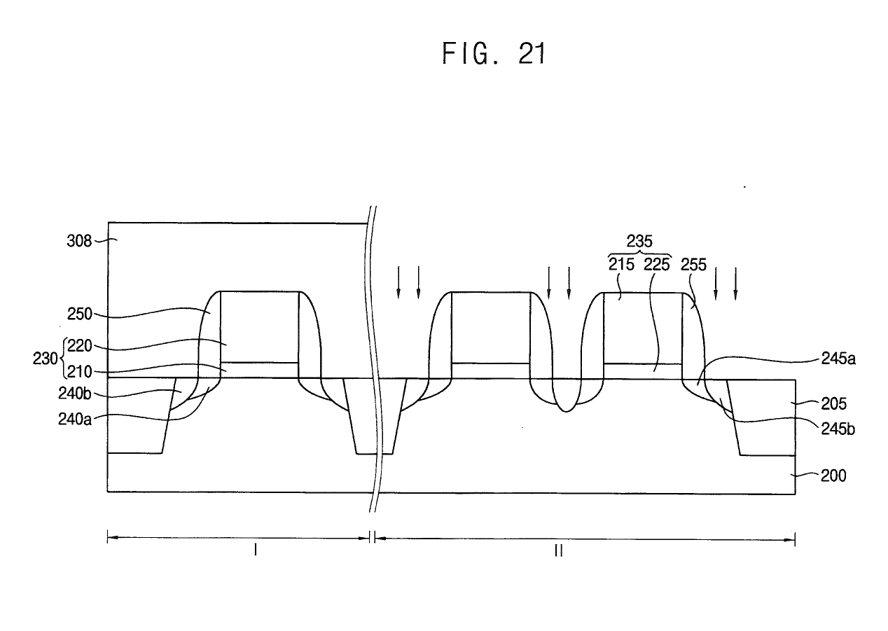

Referring to FIG. 20, after forming a third mask 306 covering the second gate structure 235, the second spacer 255 and the second crystalline ion implantation region 245a on the substrate 200 in the second region II, a first impurity region 240b may be formed at an upper portion of the substrate 200 adjacent to the first gate structure 230, by implanting first impurities into the substrate 200 using the first gate structure 230 and the first spacer 250 as an ion implantation mask. The first impurities may be n-type impurities such as phosphorus or arsenic.

Thereafter, the third mask 306 may be removed from the substrate 200.

Referring to FIG. 21, after forming a forth mask 308 covering the first gate structure 230, the first spacer 250 and the first impurity region 240b on the substrate 200 in the first region I, a second impurity region 245b may be formed at an upper portion of the substrate 200 adjacent to the second gate structure 235, by implanting third impurities into the substrate 200 using the second gate structure 235 and the second spacer 255 as an ion implantation mask. The second impurities may be p-type impurities such as boron.

Thereafter, the forth mask may be removed from the substrate 200.

By performing aforementioned processes, the semiconductor device may be completed.

According to some example embodiments, by using a stress layer including a metal nitride or a metal oxide, the stress layer may be removed using a hydrogen peroxide solution which may not react with silicon or silicon oxide afterward. As a thick etch stop layer may not need to be formed on a substrate, the stress may be transferred from the stress layer into the substrate efficiently. Additionally, an etch stop layer including silicon oxide may not need to be removed so that the damage of an isolation layer may be prevented. Moreover, as the stress layer may have a high tensile stress, a high stress may be introduced into a channel of a transistor to improve a mobility of a carrier. Meanwhile, the stress layer may not include hydrogen so that the negative bias temperature instability (NBTI) by the escape of hydrogen the may not be occurred.

The foregoing is illustrative of example embodiments and is not to be construed as limiting thereof Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of manufacturing a semiconductor device, comprising:
forming a gate structure on a substrate;
forming a diffusion barrier layer on the gate structure and the substrate;
forming a stress layer on the diffusion barrier layer comprising a metal nitride or a metal oxide having a concentration of nitrogen or oxygen associated therewith;
heating the stress layer to transform the stress layer into a tensile stress layer to reduce the concentration of the nitrogen or the oxygen in the stress layer;
removing the tensile stress layer; and
removing the diffusion barrier layer.

2. The method of claim 1, wherein the stress layer comprises a compressive stress layer prior to heating the stress layer.

3. The method of claim 1, wherein the metal nitride comprises tungsten nitride (WNₓ), ruthenium nitride (RuNₓ), cobalt nitride (CoNₓ) or nickel nitride (NiNₓ).

4. The method of claim 1, wherein the metal nitride comprises tungsten nitride (WNₓ).

5. The method of claim 4, wherein x is in a range of about 0.05 to about 0.4.

6. The method of claim 1, wherein the metal oxide comprises tungsten oxide (WO₃) or ruthenium oxide (RuO₂).

7. The method of claim 1, wherein heating the stress layer comprises heating an environment in which the stress layer is located to a temperature of about 500° C. to about 1250° C.

8. The method of claim 1, wherein removing the tensile stress layer comprises applying hydrogen peroxide solution, sulfuric acid solution or nitric acid solution to the tensile stress layer.

9. The method of claim 1, wherein the diffusion barrier layer is formed using silicon oxide (SiO₂) or silicon nitride (SiN).

10. The method of claim 1, wherein the diffusion barrier layer is formed to a thickness of about 5 Angstroms to about 20 Angstroms.

11. The method of claim 1, further comprises:
forming an amorphous ion implantation region at an upper portion of the substrate using the gate structure as an ion implantation mask prior to forming the diffusion barrier layer.

12. The method of claim 11, wherein heating the stress layer to transform the stress layer into a tensile stress layer comprises heating the stress layer to transform the amorphous ion implantation region into a crystalline ion implantation region having a compressive stress.

13. The method of claim 11, wherein forming the amorphous ion implantation region comprises implanting silicon ions or germanium ions into the substrate.

14. The method of claim 11, further comprising:
forming a spacer on a sidewall of the gate structure after forming the amorphous ion implantation region.

15. The method of claim 1, further comprising:
forming an impurity region at an upper portion of the substrate adjacent to the gate structure.

16. The method of claim 15, wherein forming the impurity region comprises forming the impurity region using n-type impurities.

17. A method of manufacturing a strained semiconductor device, comprising:
forming a first gate structure and a second gate structure on a substrate;
sequentially forming a diffusion barrier layer and a stress layer on the gate structures and the substrate, the stress layer comprising a metal nitride or a metal oxide;
performing a first heat treatment to transform the stress layer into a tensile stress layer to reduce the concentration of the nitrogen or the oxygen in the stress layer;
removing the tensile stress layer and the diffusion barrier layer;
sequentially forming an etch stop layer and a compressive stress layer on the gate structures and the substrate, the compressive stress layer comprising silicon nitride;
performing a second heat treatment on the substrate; and
removing the compressive stress layer and the etch stop layer.

18. The method of claim 17, further comprising:
forming a first amorphous ion implantation region by implanting ions into the substrate using the first gate structure as an ion implantation mask prior to forming the stress layer; and
forming a second amorphous ion implantation region by implanting ions into the substrate using the second gate structure as an ion implantation mask prior to forming the compressive stress layer;
wherein the first amorphous ion implantation region is transformed into a first crystalline ion implantation region having a compressive stress by the first heat treatment; and
the second amorphous ion implantation region is transformed into a second crystalline ion implantation region having a tensile stress by the second heat treatment.

19. The method of claim 18, wherein the diffusion barrier layer is formed using silicon oxide or silicon nitride, and the etch stop layer is formed using silicon oxide.

20. The method of claim 18, further comprising:
forming a first impurity region by doping n-type impurities at an upper portion of the substrate adjacent to the first gate structure; and
forming a second impurity region by doping p-type impurities at an upper portion of the substrate adjacent to the second gate structure.

21. A method of forming a semiconductor device, comprising:
forming a stress layer and a diffusion barrier layer on a gate structure, the stress layer comprising a metal nitride or a metal oxide having an initial concentration of nitrogen associated therewith;
heating the stress layer to transform the stress layer into a tensile stress layer to reduce the initial concentration of the nitrogen to less than about 0.06 Cn in the stress layer;
removing the tensile stress layer; and
removing the diffusion barrier layer.

22. The method of claim 21 wherein the initial concentration of nitrogen is less than about 0.5 Cn.

23. The method of claim 21 wherein heating the stress layer to transform the stress layer into a tensile stress layer changes a stress associated with the stress layer by more than about 2 Gpa.

24. The method of claim 21 further comprising:
forming an etch stop layer and a compressive stress layer on the gate structure, the compressive stress layer comprising silicon nitride;
heating the compressive stress layer; and
removing the compressive stress layer and the etch stop layer.

25. The method of claim 21, wherein the diffusion barrier layer is formed to a thickness of about 5 Angstroms to about 20 Angstroms,

26. The method of claim 21 wherein removing the tensile stress layer comprises removing the tensile stress layer using a hydrogen peroxide solution.

27. The method of claim 21 wherein the stress layer is substantially free of hydrogen.
